(19) United States
(12) Patent Application Publication
(10) Pub. No.: US 2025/0248174 A1
(43) Pub. Date: Jul. 31, 2025

(54) LIGHT-EMITTING ELEMENT, FABRICATION METHOD FOR LIGHT-EMITTING ELEMENT, QUANTUM DOT LIGHT-EMITTING DIODE, AND QUANTUM DOT DISPLAY PANEL

(71) Applicants: Hefei Visionox Technology Co., Ltd., Hefei (CN); Yungu (Gu’an) Technology Co., Ltd., Langfang (CN)

(72) Inventors: Fuxing JIAO, Hefei (CN); Zhimin YAN, Hefei (CN); Liang SU, Hefei (CN); Fengjie JIN, Hefei (CN)

(73) Assignees: Hefei Visionox Technology Co., Ltd., Hefei (CN); Yungu (Gu’an) Technology Co., Ltd., Langfang (CN)

(21) Appl. No.: 19/008,632

(22) Filed: Jan. 3, 2025

(30) Foreign Application Priority Data
Jan. 29, 2024 (CN) 202410122589.6

(51) Int. Cl. H10H 20/812; H10H 29/24

(52) U.S. Cl. CPC H10H 20/812; H10H 29/24

(57) ABSTRACT

The present application discloses a light-emitting element, a fabrication method for a light-emitting element, and a quantum dot display panel. The light-emitting element includes a light-emitting layer, a first hole transport layer, and a second hole transport layer, where the first hole transport layer is disposed at a side of the light-emitting layer; and the second hole transport layer is disposed between the first hole transport layer and the light-emitting layer, the second hole transport layer including a second hole transport material host and a plurality of photosensitive groups that crosslink the second hole transport material host, with a hole mobility of the first hole transport layer being greater than that of the second hole transport layer. The light-emitting element according to the present application exhibits good light-emitting performance.

### CROSS-REFERENCE TO RELATED APPLICATIONS

The present application claims priority to Chinese Patent Application No. 202410122589.6, entitled “LIGHT-EMITTING ELEMENT, FABRICATION METHOD FOR LIGHT-EMITTING ELEMENT, AND QUANTUM DOT DISPLAY PANEL,” filed on Jan. 29, 2024, the entire contents of which are incorporated herein by reference.

### TECHNICAL FIELD

The present application relates to the field of display technologies, and in particular to a light-emitting element, a fabrication method for a light-emitting element, and a quantum dot display panel.

### BACKGROUND

Since quantum dots (QDs) have the characteristics such as size-tunable luminescence, narrow full width at half maximum, high photoluminescence efficiency, and thermal stability, quantum dot light-emitting diodes (QLEDs), which use quantum dots as luminescent centers, have become highly promising next-generation light-emitting devices.

However, the light-emitting performance of such light-emitting elements with quantum dots still needs improvement.

### SUMMARY

The objective of the present application is to provide a light-emitting element, a fabrication method for a light-emitting element, and a quantum dot display panel, aiming to address the problem that the light-emitting performance of light-emitting elements with quantum dots still needs improvement.

In a first aspect of the present application, a light-emitting element is provided. The light-emitting element includes:
a light-emitting layer;
a first hole transport layer disposed at a side of the light-emitting layer; and
a second hole transport layer disposed between the first hole transport layer and the light-emitting layer, the second hole transport layer including a plurality of photosensitive groups, with a hole mobility of the first hole transport layer being greater than that of the second hole transport layer.

and (and (and (and (and nand nand nand nIn a second aspect of the present application, a fabrication method for a light-emitting element is provided. The method includes:
providing a substrate;
fabricating a first hole transport layer on the substrate;
disposing a first material on the first hole transport layer, the first material including a second hole transport material host and a photosensitive reactant, and exposing a first target region to excite the photosensitive reactant within the first target region into a plurality of photosensitive groups that crosslink the second hole transport material host; and
disposing a first light-emitting material on the first material, and developing the first material and the first light-emitting material to form a light-emitting layer and a second hole transport layer in the first target region, such that the light-emitting element is fabricated,
where a hole mobility of the first hole transport layer is greater than that of the second hole transport layer.

In a third aspect of the present application, a quantum dot light-emitting diode is provided. The quantum dot light-emitting diode includes:
a quantum dot light-emitting layer;
a first hole transport layer disposed at a side of the quantum dot light-emitting layer; and
a second hole transport layer disposed between the first hole transport layer and the quantum dot light-emitting layer, the second hole transport layer including a second hole transport material host and a plurality of photosensitive groups that crosslink the second hole transport material host, with a hole mobility of the first hole transport layer being greater than that of the second hole transport layer.

and (and (and (and (and nand nand nand nIn a fourth aspect of the present application, a quantum dot display panel is provided. The quantum dot display panel includes: a light-emitting element as provided in the first aspect, or a light-emitting element fabricated by a fabrication method as provided in the second aspect.

In the light-emitting element, the fabrication method for a light-emitting element, and the quantum dot display panel according to the embodiments of the present application, by setting the second hole transport layer to include a plurality of photosensitive groups, the second hole transport layer can be patterned through photolithography. In the case where the light-emitting layer is fabricated with a light-emitting material using a direct photolithography process, residues of the light-emitting material existing outside the target region can be removed altogether in the process of patterning the second hole transport layer through photolithography, thereby preventing the light-emitting material from remaining outside the target region, such that the light-emitting element can be accurately displayed, and the contrast of the light-emitting element can be improved. By providing the first hole transport layer and the second hole transport layer, and by setting the hole mobility of the first hole transport layer to be greater than that of the second hole transport layer, the first hole transport layer can improve the electrical performance of the light-emitting element, reduce the driving voltage of the light-emitting element, and increase the service life of the light-emitting element.

### BRIEF DESCRIPTION OF THE DRAWINGS

In order to describe the technical solutions in the embodiments of the present application more clearly, the drawings required for the embodiments of the present application will be briefly introduced below. Obviously, the drawings described below are only for some of the embodiments of the present application, and for those of ordinary skill in the art, other drawings can be further obtained from these drawings without any creative effort.

FIG. 1 is a schematic diagram of a partial cross-sectional structure of a light-emitting element according to an embodiment of the present application;

FIG. 2 is a schematic diagram of a partial cross-sectional structure of a light-emitting element according to an embodiment of the present application;

FIG. 3 is a schematic diagram of a partial cross-sectional structure of a light-emitting element according to an embodiment of the present application;

FIG. 4 is a schematic diagram of a partial cross-sectional structure of a light-emitting element according to an embodiment of the present application;

FIG. 5 is a schematic flowchart of a fabrication method for a light-emitting element according to an embodiment of the present application;

FIG. 6 is a schematic flowchart of a fabrication method for a light-emitting element according to an embodiment of the present application;

FIG. 7 is a schematic flowchart of a fabrication method for a light-emitting element according to an embodiment of the present application;

FIG. 8 is a schematic flowchart of a fabrication method for a light-emitting element according to an embodiment of the present application;

FIG. 9 is a schematic flowchart of a fabrication method for a light-emitting element according to an embodiment of the present application;

FIG. 10 is a schematic flowchart of a fabrication method for a light-emitting element according to an embodiment of the present application; and

FIG. 11 is a schematic diagram of a cross-sectional structure of a quantum dot display panel according to an embodiment of the present application.

Reference numerals in the accompanying drawings are as follows:
1: light-emitting layer; 11: first light-emitting portion; 12: second light-emitting portion; 13: third light-emitting portion; 2: first hole transport layer; 21: fourth transport portion; 22: fifth transport portion; 23: sixth transport portion; 3: second hole transport layer; 31: first transport portion; 32: second transport portion; 33: third transport portion; 4: substrate; 41: bottom electrode; 42: hole injection layer; 5: electron transport layer; 6: top electrode; 7: electron injection layer; X: first direction.

### DETAILED DESCRIPTION

The implementations of the present application will be further described in detail below with reference to the accompanying drawings and embodiments. The following detailed description of the embodiments and the accompanying drawings are used to illustrate the principle of the present application in an exemplary manner, but shall not be used to limit the scope of the present application. That is, the present application is not limited to the described embodiments.

In the description of the present application, it should be noted that “a plurality of” means two or more, unless otherwise specified. The orientation or positional relationships indicated by the terms “upper”, “lower”, “left”, “right”, “inner”, “outer”, etc., are only for the convenience of describing the present application and simplifying the description, rather than indicating or implying that the apparatus or element referred to must have a particular orientation or be constructed and operated in a particular orientation, and therefore should not be construed as a limitation on the present application. In addition, the terms “first”, “second” and “third” are for descriptive purposes only and should not be construed as indicating or implying relative importance. The term “perpendicular” does not mean being perpendicular in the strict sense, but within an allowable range of tolerance. The term “parallel” does not mean being parallel in the strict sense, but within an allowable range of tolerance.

The phrase “embodiment” mentioned in the present application means that the specific features, structures and characteristics described with reference to the embodiment may be encompassed in at least one embodiment of the present application. This phrase in various places in the specification does not necessarily refer to the same embodiment or an independent or alternative embodiment exclusive of other embodiments. Those skilled in the art should understand explicitly and implicitly that the embodiments described in the present application may be combined with other embodiments.

The orientation terms in the following description all indicate directions shown in the accompanying drawings, and do not limit the specific structure in the present application. In the description of the present application, it should be further noted that, the terms “mount”, “connected”, and “connect” should be interpreted in a broad sense unless explicitly defined and limited otherwise. For example, they may be a fixed connection, a detachable connection, or an integral connection; or may mean a direct connection, or an indirect connection by means of an intermediate medium. For those of ordinary skill in the art, the specific meanings of the terms mentioned above in the present application can be construed according to specific circumstances.

Quantum dots, also known as semiconductor nanocrystals, are a new type of semiconductor nanomaterial. The quantum size effect and dielectric confinement effect endow quantum dots with unique photoluminescence and electroluminescence properties. Compared to conventional organic fluorescent dyes, quantum dots exhibit excellent optical properties, such as a high quantum yield, a high photochemical stability, resistance to photodegradation, broad excitation and narrow emission, high color purity, and tunable luminescent color by controlling the size of the quantum dots. A light-emitting layer with quantum dots can be formed by using a direct photolithography process. The direct photolithography process involves applying a mixed material of quantum dot material and photosensitive reactant on a substrate. When a target region is exposed to light, the photosensitive reactant within the target region undergoes a photo-crosslinking reaction, thereby achieving the patterning of the light-emitting layer. However, due to the Van der Waals force between the mixed material and the substrate, after direct photolithographic development of the mixed material within the target region, there may be material residues existing in other regions, and the residual quantum dot material may result in undesired light mixing, which affects the color purity of the light-emitting layer.

In order to address the above problem, the embodiments of the present application provide a light-emitting element, a fabrication method for a light-emitting element, and a quantum dot display panel. The embodiments of the light-emitting element, the fabrication method for a light-emitting element, and the quantum dot display panel are described below with reference to the accompanying drawings.

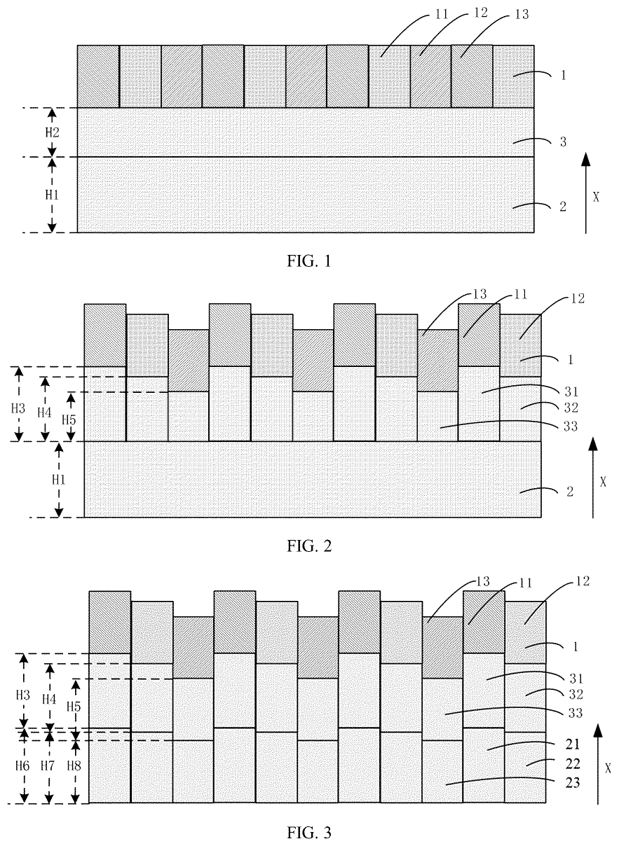

Referring to FIG. 1, in a first aspect of the present application, a light-emitting element is provided. The light-emitting element includes a light-emitting layer 1, a first hole transport layer 2, and a second hole transport layer 3, where the first hole transport layer 2 is disposed at a side of the light-emitting layer 1; and the second hole transport layer 3 is disposed between the first hole transport layer 2 and the light-emitting layer 1, the second hole transport layer 3 including a plurality of photosensitive groups, with a hole mobility of the first hole transport layer 2 being greater than that of the second hole transport layer 3.

The light-emitting layer 1 according to the present application may be a light-emitting layer based on quantum dots (QDs) technologies. The light-emitting layer 1 is provided with quantum dots, which are semiconductor nanocrystals with radii less than or close to the exciton Bohr radius. Quantum dots can be excited to produce fluorescence, and quantum dots of different sizes can emit lights of different colors. Therefore, by arranging quantum dots for emitting lights of different colors in different regions of the light-emitting layer 1, the light-emitting element can be used to display multicolor images.

Both the first hole transport layer 2 and the second hole transport layer 3 can improve the transport rate of holes in the light-emitting element, reduce the energy barrier in the injection process of holes, and improve the injection efficiency of the holes. The photosensitive groups in the second hole transport layer 3 may be introduced from a photosensitive reactant, which may be a photosensitive crosslinking molecule or a photosensitive crosslinking group. In the process of fabricating the second hole transport layer 3, the photosensitive reactant may be first added to a second hole transport material host to obtain a first material for fabricating the second hole transport layer 3. The photosensitive reactant is excited into a plurality of photosensitive groups through exposure treatment. The photosensitive groups crosslink the second hole transport material host, and the patterned second hole transport layer 3 is formed through processes such as development and photolithography.

In the case where the photosensitive reactant is a crosslinking molecule, the crosslinking molecule is mixed with the second hole transport material host to obtain the first material for fabricating the second hole transport layer 3. Under the irradiation of light waves of a preset wavelength, the crosslinking molecule is excited, such that the crosslinking molecule undergoes a crosslinking reaction to link at least two second hole transport material hosts. With the linking effect of a plurality of crosslinking molecules, a plurality of second hole transport material hosts form a grid structure.

In the case where the photosensitive reactant is a crosslinking group, the crosslinking group can be linked to the second hole transport material host through chemical bonds, so as to obtain the first material for fabricating the second hole transport layer 3. Under the irradiation of light waves of a preset wavelength, the crosslinking group is excited, such that the crosslinking group undergoes a crosslinking reaction to link at least two second hole transport material hosts. In this way, a plurality of second hole transport material hosts form a grid structure.

When fabricating the light-emitting element according to the present application, the first hole transport layer 2 can be fabricated first, and the first material for fabricating the second hole transport layer 3 is disposed on the first hole transport layer 2. The first material within the target region then undergoes exposure treatment through a mask with an opening. The light passes through the opening and irradiates the target region, such that the photosensitive reactant in the first material within the target region undergoes a photo-crosslinking reaction to form a plurality of photosensitive groups that crosslink the second hole transport material host, while regions other than the target region are blocked by the mask such that the photosensitive reactant in the regions other than the target region does not undergo a photo-crosslinking reaction. The light-emitting material is disposed on the first material, where the light-emitting material may include a quantum dot material and a photosensitive reactant. The light-emitting material within the target region undergoes exposure treatment through a mask with an opening. The light passes through the opening and irradiates the target region, such that the photosensitive reactant within the target region undergoes a photo-crosslinking reaction, while regions other than the target region are blocked by the mask such that the photosensitive reactant in the regions other than the target region does not undergo a photo-crosslinking reaction. The light-emitting material is developed to remove the light-emitting material outside the target region so as to obtain the patterned light-emitting layer 1. The first material is developed to remove the first material outside the target region so as to obtain the patterned second hole transport layer 3. Due to the development of the first material, even if residues of the first light-emitting material remain on the first material outside the target region after the development of the first light-emitting material, the first material outside the target region and the residual light-emitting material existing on the first material can be removed together through subsequent development of the first material. This prevents residues of the light-emitting material from remaining outside the target region, thereby enabling each region in the fabricated light-emitting layer 1 to emit light of a desired color, which improves the light-emitting performance of the light-emitting layer 1.

In the case where the first hole transport layer 2 is not provided, the photosensitive groups provided in the second hole transport layer 3 will reduce the hole mobility of the second hole transport layer 3, increase the driving voltage of the light-emitting element, and reduce the service life of the light-emitting element. In the light-emitting element according to the present application, the first hole transport layer 2 is disposed at a side of the second hole transport layer 3 away from the light-emitting layer 1. Since the hole mobility of the first hole transport layer 2 is greater than that of the second hole transport layer 3, the first hole transport layer 2 can improve the electrical performance of the light-emitting element, reduce the driving voltage of the light-emitting element, and increase the service life of the light-emitting element.

In this embodiment according to the present application, by setting the second hole transport layer 3 to include a plurality of photosensitive groups, the second hole transport layer 3 can be patterned through photolithography. In the case where the light-emitting layer 1 is fabricated with a light-emitting material using a direct photolithography process, residues of the light-emitting material existing outside the target region can be removed altogether in the process of patterning the second hole transport layer 3 through photolithography, thereby preventing the light-emitting material from remaining outside the target region, such that the light-emitting element can be accurately displayed, and the contrast of the light-emitting element can be improved. By providing the first hole transport layer 2 and the second hole transport layer 3, and by setting the hole mobility of the first hole transport layer 2 to be greater than that of the second hole transport layer 3, the first hole transport layer 2 can improve the electrical performance of the light-emitting element, reduce the driving voltage of the light-emitting element, and increase the service life of the light-emitting element.

In some embodiments, the first hole transport layer 2 includes a first hole transport material and a plurality of first crosslinking groups that crosslink the first hole transport material.

The first hole transport material is a material with good hole mobility and electron blocking capability. The first hole transport material enables efficient transport of holes into the second hole transport layer 3.

The crosslinking reaction refers to a reaction in which two or more molecules are bonded and crosslinked to each other to form a grid structure. The first crosslinking groups may be introduced from thermal crosslinking reactants, photosensitive reactants, or the like. By adding thermal crosslinking reactants, photosensitive reactants, or the like to the first hole transport material, under appropriate reaction conditions, these reactants undergo a crosslinking reaction to convert into the first crosslinking groups. The first crosslinking groups can link at least two molecules in the first hole transport material through a crosslinking reaction, thereby improving the stability of the formed first hole transport layer 2.

In some embodiments, the first crosslinking groups are a plurality of thermal crosslinking groups.

Heating the material for forming the first hole transport layer 2 can trigger a crosslinking reaction of the thermal crosslinking reactants within it, thus obtaining a thermal crosslinking group that crosslinks the first hole transport material, thereby improving the stability of the formed first hole transport layer 2.

In the first hole transport layer 2, the first hole transport material is crosslinked through the thermal crosslinking group, and in the second hole transport layer 3, the second hole transport material host is crosslinked through the photosensitive groups. This results in a difference in the crosslinking groups between the first hole transport layer 2 and the second hole transport layer 3, which helps reduce or avoid the impact of the development process of the second hole transport layer 3 on the first hole transport layer 2. Those skilled in the art can select a developer for forming the second hole transport layer 3, the photosensitive groups in the second hole transport layer 3, the second hole transport material host, etc., as needed, so as to reduce or avoid the impact of the process of fabricating the second hole transport layer 3 on the fabricated first hole transport layer 2.

In some embodiments, the first crosslinking groups include one or more of an aliphatic polyamine crosslinking group, an alicyclic polyamine crosslinking group, an aromatic polyamine crosslinking group, a phenolic crosslinking group, and an anhydride crosslinking group.

The thermal crosslinking reactant for introducing the aliphatic polyamine crosslinking group may include ethylenediamine, hexamethylenediamine, diethylenetriamine, etc. The thermal crosslinking reactant for introducing the alicyclic polyamine crosslinking group includes isophorone diamine, diaminomethyl cyclohexane, 4,4′-diaminodicyclohexylmethane, etc. The thermal crosslinking reactant for introducing the aromatic polyamine crosslinking group includes 4,4′-diaminodiphenylmethane, 4,4′-diaminodiphenylsulfone, meta-phenylenediamine, etc. The thermal crosslinking reactant for introducing the phenolic crosslinking group includes phenol-formaldehyde amine, aldehyde amine, aldehyde-alcohol amine, etc. The thermal crosslinking reactant for introducing the anhydride crosslinking group includes maleic anhydride, phthalic anhydride, etc.

Those skilled in the art can, based on the required temperature for the thermal crosslinking reaction, the stability of the product after crosslinking, the required hole mobility for the first hole transport layer 2, etc., select an appropriate crosslinker for forming the first crosslinking groups.

In some embodiments, a doping ratio of the first crosslinking groups in the first hole transport layer ranges from 5% to 20%.

The doping ratio of the first crosslinking groups in the first hole transport layer ranges from 5% to 20%, which is also understood to mean that a doping ratio of the thermal crosslinking reactant ranges from 5% to 20%. If the doping ratio of the first crosslinking groups is too low, it will result in insufficient stability of the formed first hole transport layer 2; whereas if the doping ratio of the first crosslinking groups is too high, it will cause the crosslinking reaction for forming the first hole transport layer 2 to occur too rapidly, leading to a risk of cracking in the formed first hole transport layer 2 and insufficient hole mobility of the formed first hole transport layer 2. Therefore, the doping ratio of the first crosslinking groups is set to 5% to 20%, which can ensure that the formed first hole transport layer 2 has an intact shape and the first hole transport layer 2 has good stability and hole mobility.

In some embodiments, the photosensitive groups include one or more of a benzophenone group and an azido-containing crosslinking group.

Those skilled in the art can, based on the stability of the product after crosslinking of the photosensitive groups, as well as the required hole mobility, transparency, refractive index, etc., for the second hole transport layer 3, select an appropriate photosensitive reactant for introducing the photosensitive groups. The benzophenone group is a group that is used to link the second hole transport material after a crosslinking reaction occurs by introducing benzophenone or a derivative of benzophenone as the crosslinking reactant.

In some embodiments, a doping ratio of the photosensitive groups in the second hole transport layer ranges from 5% to 20%.

The doping ratio of the photosensitive groups in the second hole transport layer ranges from 5% to 20%, which is also understood to mean that a doping ratio of the photosensitive reactant in the first material ranges from 5% to 20%. If the doping ratio of the photosensitive groups is too low, it will result in insufficient stability of the formed second hole transport layer 3; whereas if the doping ratio of the photosensitive groups is too high, it will result in insufficient hole mobility of the formed second hole transport layer 3. Therefore, the doping ratio of the photosensitive groups is set to 5% to 20%, which can ensure that the formed second hole transport layer 3 has an intact shape and the second hole transport layer 3 has good stability and hole mobility.

In some embodiments, the first hole transport layer 2 includes a first hole transport material, and the second hole transport layer 3 includes a second hole transport material host. At least one of the first hole transport material and the second hole transport material host is one of poly (9,9-dioctylfluorene-CO—N-(4-butylphenyl) diphenylamine) (TFB), poly (N-vinylcarbazole) (PVK), and 2,2′,7,7′-tetrakis [trimethyl]-9,9′-spirobifluorene-1,2-dioxetane (Spiro-MeOTAD).

The first hole transport layer 2 achieves hole transport through the first hole transport material. The first hole transport material is the main material of the first hole transport layer 2, and the first hole transport material is one of TFB, PVK, and Spiro-MeOTAD. The second hole transport layer 3 achieves hole transport through the second hole transport material host. The second hole transport material host is the main material of the second hole transport layer 3, and the second hole transport material host is one of TFB, PVK, and Spiro-MeOTAD. The first hole transport material and the second hole transport material host may be the same or different. In an optional embodiment, the first hole transport material and the second hole transport material host are both TFB so as to simplify the fabricating procedure.

In some embodiments, the first hole transport layer 2 has a thickness of H1, and the second hole transport layer 3 has a thickness of H2, and H1>H2.

Since the hole mobility of the first hole transport layer 2 is greater than that of the second hole transport layer 3, H1>H2 is set, so as to increase the proportion of the first hole transport layer 2 in the overall structure of the first hole transport layer 2 and the second hole transport layer 3, thereby improving the electrical performance of the light-emitting element.

Referring to FIG. 2, in some embodiments, the light-emitting layer 1 includes a first light-emitting portion 11 and a second light-emitting portion 12, the first light-emitting portion 11 being configured to emit a first-color light, and the second light-emitting portion 12 being configured to emit a second-color light, and the second hole transport layer 3 includes a first transport portion 31 and a second transport portion 32, the first transport portion 31 being located at a side of the first light-emitting portion 11 close to the first hole transport layer 2, and the second transport portion 32 being located at a side of the second light-emitting portion 12 close to the first hole transport layer 2, and the first transport portion 31 having a thickness of H3, and the second transport portion 32 having a thickness of H4, and H3+H4.

In the case where the light-emitting layer 1 is a quantum dot light-emitting layer, the quantum dots provided in the first light-emitting portion 11 and the second light-emitting portion 12 are different. In the case where the quantum dots in the light-emitting portion are red quantum dots, the light-emitting portion is configured to be excited to produce a red light. In the case where the quantum dots in the light-emitting portion are green quantum dots, the light-emitting portion is configured to be excited to produce a green light. In the case where the quantum dots in the light-emitting portion are blue quantum dots, the light-emitting portion is configured to be excited to produce a blue light. The first-color light and the second-color light may be any two of red light, green light, and blue light, with different wavelengths for the first-color light and the second-color light. This allows control of the coordinated light emission from the first light-emitting portion 11 and the second light-emitting portion 12, thereby achieving light-emitting display in different colors.

When the light-emitting layer 1 is excited to emit light, part of the light passes directly through part of functional layers in the light-emitting element and exits from a light output side of the light-emitting element, and another part of the light is reflected by part of the functional layers in the light-emitting element and then exits from the light output side of the light-emitting element. The light undergoes optical interference phenomena after one or more reflections within the light-emitting element. The light can travel through the second hole transport layer 3 towards reflective surfaces of part of the functional layers. Thus, by controlling the thickness of the second hole transport layer 3, the optical interference phenomena can be regulated, thereby achieving a microcavity effect and improving the light extraction efficiency.

Since the microcavity effect is related to the wavelength of the light and the propagation path of the light, for the first light-emitting portion 11 and the second light-emitting portion 12, which are applied to emit lights of different colors, H3+H4 is set, such that the microcavity effect can be realized separately for the first-color light emitted from the first light-emitting portion 11 and the second-color light emitted from the second light-emitting portion 12, thereby improving the light extraction efficiency of the first-color light and the light extraction efficiency of the second-color light.

The light-emitting element may further include a bottom electrode and a hole injection layer. The bottom electrode, the hole injection layer, the first hole transport layer 2, and the second hole transport layer 3 are sequentially stacked along a first direction X. Part of the light emitted by the light-emitting layer 1 passes through the second hole transport layer 3, the first hole transport layer 2, and the hole injection layer, and is then reflected by the bottom electrode. By controlling the overall thickness of the second hole transport layer 3, the first hole transport layer 2, and the hole injection layer along the first direction X, the propagation route of part of the light emitted by the light-emitting layer 1 can be controlled, thereby achieving the microcavity effect. In the case where the thicknesses of the first hole transport layer 2 and the hole injection layer are uniform, by controlling the thickness of the second hole transport layer 3, the propagation route of part of the light emitted by the light-emitting layer 1 can be controlled, thereby achieving the microcavity effect.

For example, the first light-emitting portion 11 is configured to emit red light and the second light-emitting portion 12 is configured to emit green light. In the case where the thicknesses of the first hole transport layer 2 and the hole injection layer along the first direction X are uniform, H3/H4 is set, thereby changing the propagation path of the red light through the second hole transport layer 3, the first hole transport layer 2, and the hole injection layer 42, and the propagation path of the green light through the second hole transport layer 3, the first hole transport layer 2, and the hole injection layer 42, such that the microcavity effect can be achieved for both the red light and the green light, thereby improving the light extraction efficiency of the red light and the green light.

In some embodiments, when a wavelength of the first-color light is greater than a wavelength of the second-color light, H3>H4.

In the case where the mode numbers m for the microcavity effect required for emitting the first-color light and the second-color light are consistent, and the wavelength of the first-color light is greater than that of the second-color light, H3>H4 can be set to improve the light extraction efficiency of the first-color light and the light extraction efficiency of the second-color light.

In some embodiments, the light-emitting layer 1 further includes a third light-emitting portion 13, the third light-emitting portion 13 being configured to emit a third-color light, and the second hole transport layer 3 further includes a third transport portion 33, the third transport portion 33 being located at a side of the third light-emitting portion 13 close to the first hole transport layer 2, and the third transport portion 33 having a thickness of H5, and H3, H4, and H5 being different from each other.

The first light-emitting portion 11, the second light-emitting portion 12, and the third light-emitting portion 13 may be a red light-emitting portion, a green light-emitting portion, and a blue light-emitting portion, respectively. In addition, they can also be light-emitting portions for emitting lights of other colors than red, green, and blue. The wavelengths of the first-color light, the second-color light, and the third-color light are different, and then H3, H4, and H5 can be set differently, so as to achieve the microcavity effect for the first-color light emitted by the first light-emitting portion 11, the second-color light emitted by the second light-emitting portion 12, and the third-color light emitted by the third light-emitting portion 13, thereby improving the light extraction efficiency of the first-color light, the light extraction efficiency of the second-color light, and the light extraction efficiency of the third-color light.

In some embodiments, when the wavelength of the second-color light is greater than a wavelength of the third-color light, H4>H5.

In the case where the mode numbers m for the microcavity effect required for emitting the second-color light and the third-color light are consistent, and the wavelength of the second-color light is greater than that of the third-color light, H4>H5 can be set to improve the light extraction efficiency of the second-color light and the light extraction efficiency of the third-color light.

For example, the first light-emitting portion 11 is configured to emit the red light, the second light-emitting portion 12 is configured to emit the green light, and the third light-emitting portion 13 is configured to emit the blue light. In the case where the thicknesses of the first hole transport layer 2 and the hole injection layer along the first direction X are uniform, H3>H4>H5 is set, thereby changing the propagation path of the red light through the second hole transport layer 3, the first hole transport layer 2, and the hole injection layer, the propagation path of the green light through the second hole transport layer 3, the first hole transport layer 2, and the hole injection layer, and the propagation path of the blue light through the second hole transport layer 3, the first hole transport layer 2, and the hole injection layer, such that the microcavity effect can be achieved for the red light, the green light, and the blue light, thereby improving the light extraction efficiency of the red light, the green light, and the blue light.

Referring to FIG. 3, in some embodiments, the light-emitting layer 1 includes a first light-emitting portion 11 and a second light-emitting portion 12, the first light-emitting portion 11 being configured to emit a first-color light, and the second light-emitting portion 12 being configured to emit a second-color light, and the second hole transport layer 3 includes a first transport portion 31 and a second transport portion 32, and the first hole transport layer 2 includes a fourth transport portion 21 and a fifth transport portion 22, the first light-emitting portion 11, the first transport portion 31, and the fourth transport portion 21 being sequentially stacked along a first direction X, and the second light-emitting portion 12, the second transport portion 32, and the fifth transport portion 22 being sequentially stacked along the first direction X, and the first transport portion 31 having a thickness of H3, the second transport portion 32 having a thickness of H4, the fourth transport portion 21 having a thickness of H6, and the fifth transport portion 22 having a thickness of H7, and (H3+H6)/(H4+H7).

In this embodiment, not only can the thicknesses of the first transport portion 31 and the second transport portion 32 be set differently, i.e., H3+H4, but also can the thicknesses of the fourth transport portion 21 and the fifth transport portion 22 be set differently, i.e., H6≠H7, and (H3+H6)≠(H4+H7) can be set. In this way, the propagation path of the first-color light through the second hole transport layer 3, the first hole transport layer 2, and the hole injection layer, and the propagation path of the second-color light through the second hole transport layer 3, the first hole transport layer 2, and the hole injection layer are changed, such that the microcavity effect can be achieved for both the first-color light and the second-color light, thereby improving the light extraction efficiency of the first-color light and the second-color light.

In some embodiments, when a wavelength of the first-color light is greater than a wavelength of the second-color light, (H3+H6)> (H4+H7).

In the case where the mode numbers m for the microcavity effect required for emitting the first-color light and the second-color light are consistent, and the wavelength of the first-color light is greater than that of the second-color light, (H3+H6)> (H4+H7) can be set to improve the light extraction efficiency of the first-color light and the light extraction efficiency of the second-color light.

In some embodiments, the light-emitting layer 1 further includes a third light-emitting portion 13, the third light-emitting portion 13 being configured to emit a third-color light, the second hole transport layer 3 further includes a third transport portion 33, and the first hole transport layer 2 includes a sixth transport portion 23, the third light-emitting portion 13, the third transport portion 33, and the sixth transport portion 23 being sequentially stacked along the first direction, and the third transport portion 33 having a thickness of H5, and the sixth transport portion 23 having a thickness of H8, and (H3+H6), (H4+H7), and (H5+H8) being different from each other.

In this embodiment, not only can the thicknesses of the first transport portion 31, the second transport portion 32, and the third transport portion 33 be set differently, that is, H3, H4, and H5 are different from each other, but also can the thicknesses of the fourth transport portion 21, the fifth transport portion 22, and the sixth transport portion 23 be set differently, that is, H6, H7, and H8 are different from each other, and (H3+H6), (H4+H7), and (H5+H8) can be made different from each other. In this way, the propagation path of the first-color light through the second hole transport layer 3, the first hole transport layer 2, and the hole injection layer, the propagation path of the second-color light through the second hole transport layer 3, the first hole transport layer 2, and the hole injection layer, and the propagation path of the third-color light through the second hole transport layer 3, the first hole transport layer 2, and the hole injection layer are changed, such that the microcavity effect can be achieved for the first-color light, the second-color light, and the third-color light, thereby improving the light extraction efficiency of the first-color light, the second-color light, and the third-color light.

In some embodiments, when the wavelength of the second-color light is greater than a wavelength of the third-color light, (H4+H7)> (H5+H8).

In the case where the mode numbers m for the microcavity effect required for emitting the second-color light and the third-color light are consistent, and the wavelength of the second-color light is greater than that of the third-color light, (H4+H7)> (H5+H8) can be set to improve the light extraction efficiency of the second-color light and the light extraction efficiency of the third-color light.

The thicknesses of the fourth transport portion 21, the fifth transport portion 22, and the sixth transport portion 23 are different, then the capabilities of the fourth transport portion 21, the fifth transport portion 22, and the sixth transport portion 23 to supply holes to the corresponding light-emitting portions are also different. Therefore, by adjusting the thicknesses of the fourth transport portion 21, the fifth transport portion 22, and the sixth transport portion 23, the light-emitting portions for emitting lights of different colors can be adjusted to have different light-emitting performance.

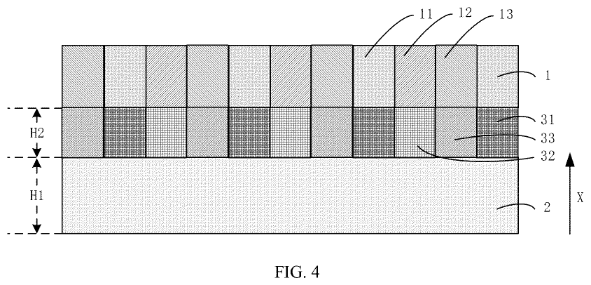

Referring to FIG. 4, in some embodiments, the light-emitting layer 1 includes a first light-emitting portion 11 and a second light-emitting portion 12, the first light-emitting portion 11 being configured to emit a first-color light, and the second light-emitting portion 12 being configured to emit a second-color light, and the second hole transport layer 3 includes a first transport portion 31 and a second transport portion 32, the first transport portion 31 being located at a side of the first light-emitting portion 11 close to the first hole transport layer 2, and the second transport portion 32 being located at a side of the second light-emitting portion 12 close to the first hole transport layer 2, and the first transport portion 31 having a refractive index of n1, and the second transport portion 32 having a refractive index of n2, and n1≠n2.

The microcavity effect is related not only to the propagation route of the light, but also to the refractive index of the medium through which the light passes. By setting n1≠n2, the microcavity effect can be achieved for both the first-color light and the second-color light, thereby improving the light extraction efficiency of the first-color light and the second-color light.

When fabricating the light-emitting element according to the present application, the first hole transport layer 2 can be fabricated first, the first material for fabricating the second hole transport layer 3 is disposed on the first hole transport layer 2, and the first light-emitting material is disposed on the first material. The first light-emitting material is developed to remove the first light-emitting material outside the first target region so as to obtain the patterned first light-emitting portion 11, and the first material is developed to remove the first material outside the first target region so as to obtain the patterned first transport portion 31. The second material for fabricating the second hole transport layer 3 is disposed on the first transport portion 31 and the first light-emitting portion 11, and the second light-emitting material is disposed on the second material. The second light-emitting material is developed to remove the second light-emitting material outside the second target region so as to obtain the patterned second light-emitting portion 12, and the second material is developed to remove the second material outside the second target region so as to obtain the patterned second transport portion 32. That is, since the materials used for the first light-emitting portion 11 and the second light-emitting portion 12 are different, the first light-emitting portion 11 and the second light-emitting portion 12 need to be fabricated in separate steps, and the first transport portion 31 and the second transport portion 32 also need to be fabricated in separate steps along with the first light-emitting portion 11 and the second light-emitting portion 12. Therefore, fabricating the first transport portion 31 and the second transport portion 32 by using materials of different refractive indexes can achieve n1+n2.

In some embodiments, when a wavelength of the first-color light is greater than a wavelength of the second-color light, n1>n2.

In the case where the propagation route of the first-color light in the microcavity is consistent with the propagation route of the second-color light in the microcavity, since the wavelength of the first-color light is greater than the wavelength of the second-color light, n1>n2 may be set such that the microcavity effect can be achieved for both the first-color light and the second-color light, thereby improving the light extraction efficiency of the first-color light and the second-color light.

In some embodiments, the light-emitting layer 1 further includes a third light-emitting portion 13, the third light-emitting portion 13 being configured to emit a third-color light, and the second hole transport layer 3 further includes a third transport portion 33, the third transport portion 33 being located at a side of the third light-emitting portion 13 close to the first hole transport layer 2, and the third transport portion 33 having a refractive index of n3, and n1, n2, and n3 being different from each other.

The first light-emitting portion 11, the second light-emitting portion 12, and the third light-emitting portion 13 may be a red light-emitting portion, a green light-emitting portion, and a blue light-emitting portion, respectively. In addition, they can also be light-emitting portions for emitting lights of other colors than red, green, and blue. The wavelengths of the first-color light, the second-color light, and the third-color light are different, and then n1, n2, and n3 can be set differently, so as to achieve the microcavity effect for the first-color light emitted by the first light-emitting portion 11, the second-color light emitted by the second light-emitting portion 12, and the third-color light emitted by the third light-emitting portion 13, thereby improving the light extraction efficiency of the first-color light, the light extraction efficiency of the second-color light, and the light extraction efficiency of the third-color light.

In some embodiments, when the wavelength of the second-color light is greater than a wavelength of the third-color light, n2>n3.

For example, the first light-emitting portion 11 is configured to emit the red light, the second light-emitting portion 12 is configured to emit the green light, and the third light-emitting portion 13 is configured to emit the blue light. In the case where the thicknesses of the second hole transport layer 3, the first hole transport layer 2, and the hole injection layer 42 along the first direction are uniform, n1>n2>n3 is set, thereby changing the propagation path of the red light through the second hole transport layer 3, the first hole transport layer 2, and the hole injection layer 42, the propagation path of the green light through the second hole transport layer 3, the first hole transport layer 2, and the hole injection layer 42, and the propagation path of the blue light through the second hole transport layer 3, the first hole transport layer 2, and the hole injection layer 42, such that the microcavity effect can be achieved for the red light, the green light, and the blue light, thereby improving the light extraction efficiency of the red light, the green light, and the blue light.

In a second aspect of the present application, a fabrication method for a light-emitting element is provided. The method includes the following steps.

S100: Provide a substrate.

S200: Fabricate a first hole transport layer on the substrate.

S300: Dispose a first material on the first hole transport layer, the first material including a second hole transport material host and a photosensitive reactant, and expose a first target region to excite the photosensitive reactant within the first target region into a plurality of photosensitive groups that crosslink the second hole transport material host.

S400: Dispose a first light-emitting material on the first material, and develop the first material and the first light-emitting material to form a light-emitting layer and a second hole transport layer in the first target region, such that the light-emitting element is fabricated, where a hole mobility of the first hole transport layer is greater than that of the second hole transport layer.

The substrate supports different materials as a support to form the first hole transport layer 2, the second hole transport layer 3, the light-emitting layer 1, etc. The substrate can be a rigid plate-like structure fabricated in advance. Optionally, the substrate includes a bottom electrode, a hole injection layer, etc.

In S200, the first hole transport layer can be fabricated by using a mixed material having a first hole transport material and a crosslinking reactant. In the case where the crosslinking reactant is a thermal crosslinking reactant, the mixed material is disposed on the substrate, and the mixed material is heated to cause the thermal crosslinking reactant to undergo a crosslinking reaction such that the thermal crosslinking reactant is excited into the first crosslinking groups that crosslink the first hole transport material and is then cured to form the first hole transport layer.

In S300 and S400, the same mask can be used for exposure treatment of the first material and the first light-emitting material. The mask has a preset pattern opening, and the mask is disposed at a side of the first material or the first light-emitting material. Light waves with a preset wavelength are used to expose the first target region through the mask. Under the effect of the light waves with the preset wavelength, the photosensitive reactant in the first material or the photosensitive reactant in the first light-emitting material undergoes a photo-crosslinking reaction, thereby causing the first material located within the first target region to cure or the first light-emitting material located within the first target region to cure.

In S400, the first light-emitting material is developed using a developer that can dissolve the first light-emitting material, and the first material is developed using a developer that can dissolve the first material, so as to remove the first material and the first light-emitting material located outside the first target region and retain the first material and the first light-emitting material within the first target region, thereby obtaining the patterned light-emitting layer 1 and second hole transport layer 3 that are consistent with the pattern of the preset pattern opening.

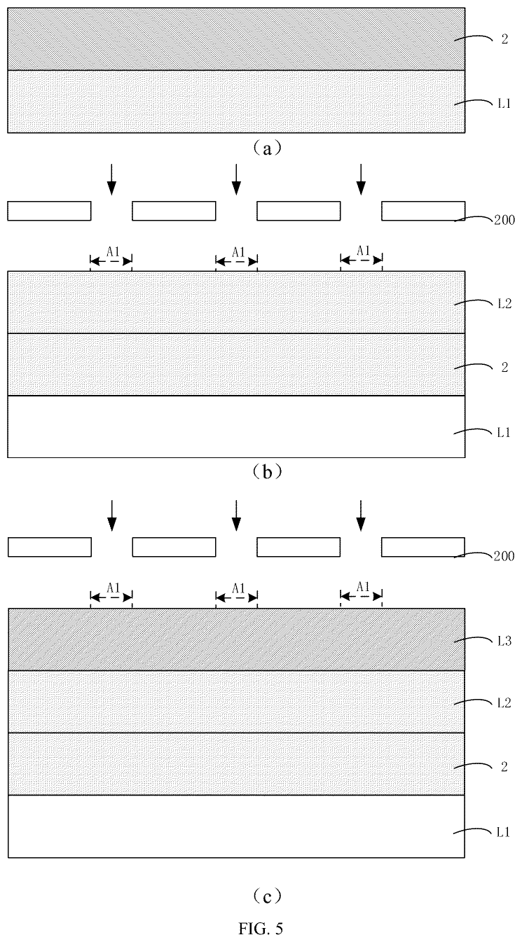

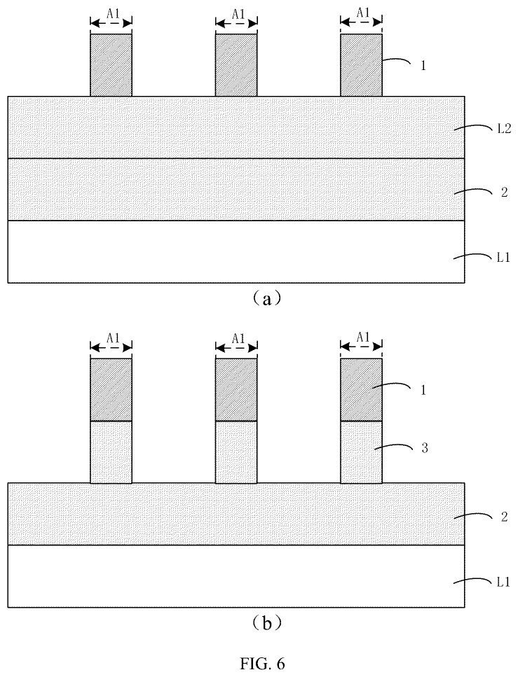

For example, referring to (a) in FIG. 5, the mixed material is disposed on a substrate L1, and the mixed material is heated to obtain the cured first hole transport layer 2. Referring to (b) in FIG. 5, a first material L2 is disposed on the first hole transport layer 2, and a mask 200 with a preset pattern opening is used to expose a first target region A1. Referring to (c) in FIG. 5, a first light-emitting material L3 is disposed on the first material L2, and the mask 200 with the preset pattern opening is used to expose the first target region A1. Referring to (a) in FIG. 6, the first light-emitting material L3 is developed to remove the first light-emitting material L3 located outside the first target region A1 so as to obtain the patterned light-emitting layer 1. Referring to (b) in FIG. 6, the first material L2 is developed to remove the first material L2 located outside the first target region A1 so as to obtain the patterned second hole transport layer 3.

In this embodiment of the present application, the second hole transport layer 3 and the light-emitting layer 1 in the light-emitting element are formed through a photolithography process, which can improve the uniformity of the morphology and thicknesses of the second hole transport layer 3 and the light-emitting layer 1, and enhance the fineness of the patterned second hole transport layer 3 and light-emitting layer 1, thereby improving the resolution of the light-emitting element. A light-emitting element fabricated by the fabrication method for a light-emitting element according to the embodiment of the present application has the related structure of the aforementioned light-emitting element. For more details, reference can be made to the light-emitting element according to the aforementioned embodiments. This light-emitting element has all the beneficial effects of the aforementioned light-emitting element, which will not be repeated here.

In some embodiments, S400 includes the following steps.

S410: Dispose the first light-emitting material on the first material, and expose the first target region to cause a photo-crosslinking reaction of the first light-emitting material within the first target region.

S420: Develop the first light-emitting material to dissolve the first light-emitting material outside the first target region to obtain the light-emitting layer.

S430: Develop the first material to dissolve the first material outside the first target region to obtain the second hole transport layer.

In this embodiment, since the first light-emitting material and the first material are different, the first material and the first light-emitting material are developed in separate steps, which will reduce or avoid residues of the first light-emitting material outside the first target region, thereby improving the fineness of the fabricated light-emitting element.

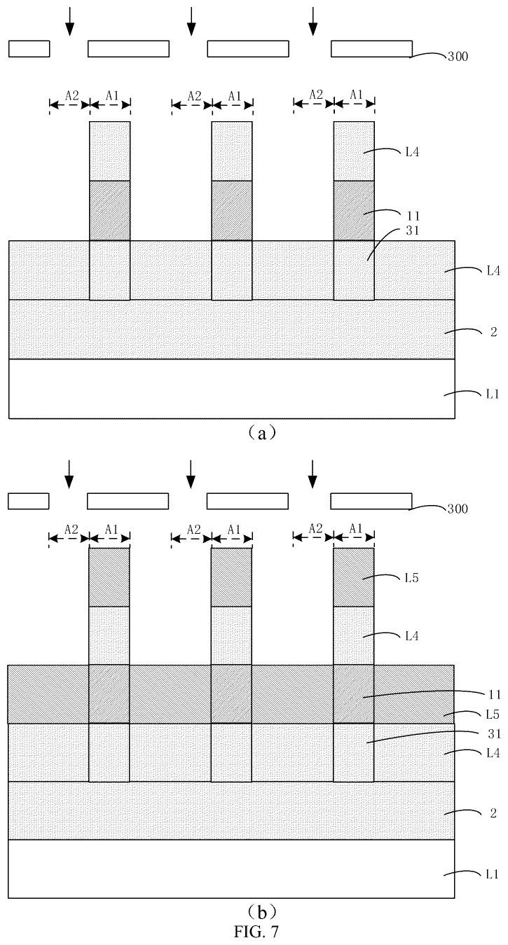

Referring to FIG. 7, in some embodiments, the first light-emitting material is developed to obtain a first light-emitting portion 11 for emitting a first-color light, and the first material is developed to obtain a first transport portion 31 connected to the first light-emitting portion 11. After S430, the method further includes the following steps.

S440: Dispose a second material on the first hole transport layer and the first light-emitting material, the second material including a second hole transport material host and a photosensitive reactant, and expose a second target region to excite the photosensitive reactant within the second target region into a plurality of photosensitive groups that crosslink the second hole transport material host.

S450: Dispose a second light-emitting material on the second material, and develop the second material and the second light-emitting material to form a second transport portion and a second light-emitting portion for emitting a second-color light in the second target region, such that the light-emitting element is fabricated.

After the first transport portion 31 and the first light-emitting portion 11 are fabricated, the second transport portion 32 and the second light-emitting portion 12 may be further fabricated as desired. After the second transport portion 32 and the second light-emitting portion 12 are fabricated, the third transport portion and the third light-emitting portion may be further fabricated as desired, and so on, until a desired number and types of light-emitting portions are fabricated.

The refractive index of the second material may be different from that of the first material, such that the refractive index of the formed first transport portion 31 is different from that of the formed second transport portion 32. The thickness of the second material disposed on the first hole transport layer 2 may be different from that of the first material disposed on the first hole transport layer 2, such that the thickness of the formed first transport portion 31 is different from that of the formed second transport portion 32.

The mask used for fabricating the first transport portion 31 and the first light-emitting portion 11 is different from the mask used for fabricating the second transport portion 32 and the second light-emitting portion 12. The two masks have different preset pattern openings, so that the fabricated first light-emitting portion 11 will not have the second light-emitting portion 12 stacked on it, and orthographic projections of the formed first light-emitting portion 11 and the formed second light-emitting portion 12 on the first hole transport layer 2 are spaced from each other.

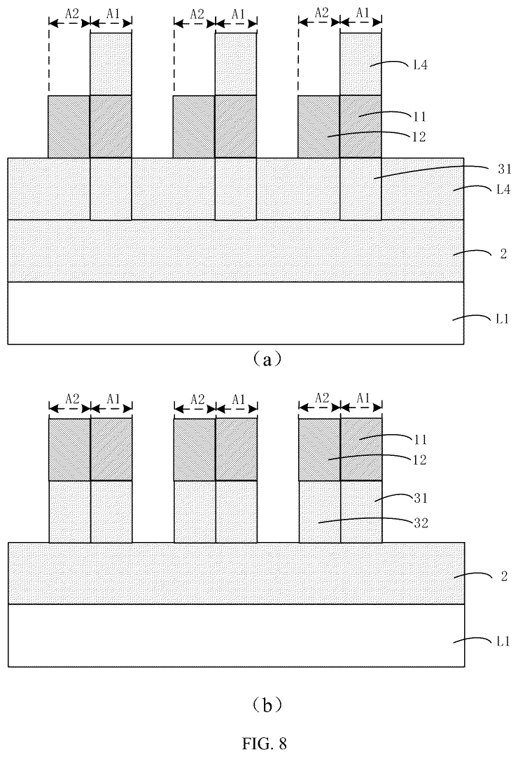

For example, referring to (a) in FIG. 7, a second material L4 is disposed on the first hole transport layer 2 and the first light-emitting portion 11, and a mask 300 with a preset pattern opening is used to expose a second target region A2. Referring to (b) in FIG. 7, a second light-emitting material L5 is disposed on the second material L4, and the mask 300 with the preset pattern opening is used to expose the second target region A2. Referring to (a) in FIG. 8, the second light-emitting material L5 is developed to remove the second light-emitting material L5 located outside the second target region A2 so as to obtain the patterned second light-emitting portion 12. Referring to (b) in FIG. 8, the second material L4 is developed to remove the second material L4 located outside the second target region A2 so as to obtain the patterned second transport portion 32.

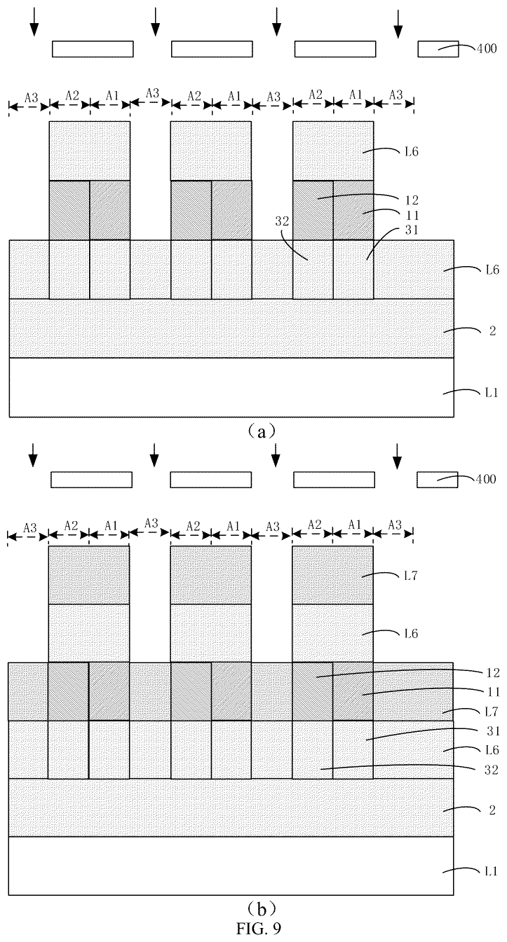

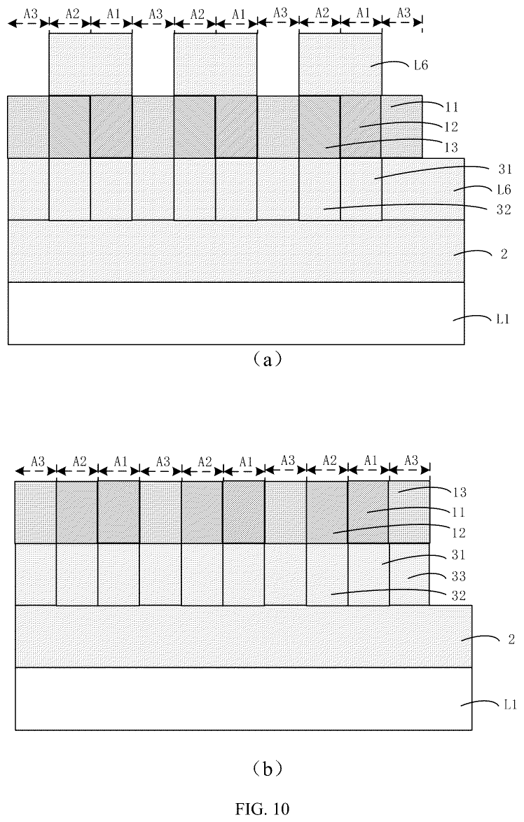

For example, referring to (a) in FIG. 9, a third material L6 is disposed on the first hole transport layer 2, the first light-emitting portion 11, and the second light-emitting portion 12, and a mask 400 with a preset pattern opening is used to expose a third target region A3. Referring to (b) in FIG. 9, a third light-emitting material L7 is disposed on the third material L6, and the mask 400 with the preset pattern opening is used to expose the third target region A3. Referring to (a) in FIG. 10, the third light-emitting material L7 is developed to remove the third light-emitting material L7 located outside the third target region A3 so as to obtain the patterned third light-emitting portion 13. Referring to (b) in FIG. 10, the third material L6 is developed to remove the third material L6 located outside the third target region A3 so as to obtain the patterned third transport portion 33.

The fabricated first light-emitting portion 11 has quantum dots for emitting the first-color light, and the fabricated second light-emitting portion 12 has quantum dots for emitting the second-color light, such that the first light-emitting portion 11 can be excited to emit the first-color light, and the second light-emitting portion 12 can be excited to emit the second-color light. The patterned first light-emitting portion 11 and second light-emitting portion 12 are both disposed on the second hole transport layer 3, and different patterns can be displayed by exciting different regions of the first light-emitting portion 11 and the second light-emitting portion 12 to emit light.

In a third aspect of the present application, a quantum dot light-emitting diode is provided. The quantum dot light-emitting diode includes:
a quantum dot light-emitting layer;
a first hole transport layer disposed at a side of the quantum dot light-emitting layer; and
a second hole transport layer disposed between the first hole transport layer and the quantum dot light-emitting layer, the second hole transport layer including a second hole transport material host and a plurality of photosensitive groups that crosslink the second hole transport material host, with a hole mobility of the first hole transport layer being greater than that of the second hole transport layer.

The quantum dot light-emitting layer according to the present application may be a light-emitting layer based on quantum dots (QDs) technologies. The quantum dot light-emitting layer contains quantum dots of different sizes.

In this embodiment according to the present application, by setting the second hole transport layer to include a plurality of photosensitive groups, the second hole transport layer can be patterned through photolithography. In the case where the quantum dot light-emitting layer is fabricated with a light-emitting material using a direct photolithography process, residues of the light-emitting material existing outside the target region can be removed altogether in the process of patterning the second hole transport layer through photolithography, thereby preventing the light-emitting material from remaining outside the target region, such that the light-emitting element can be accurately displayed, and the contrast of the light-emitting element can be improved. By providing the first hole transport layer and the second hole transport layer, and by setting the hole mobility of the first hole transport layer to be greater than that of the second hole transport layer, the first hole transport layer can improve the electrical performance of the light-emitting element, reduce the driving voltage of the light-emitting element, and increase the service life of the light-emitting element.

In some embodiments, the photosensitive groups include one or more of a benzophenone group and an azido-containing group.

In some embodiments, a doping ratio of the photosensitive groups ranges in the second hole transport layer from 5% to 20%.

In some embodiments, the first hole transport layer has a thickness of H1, and the second hole transport layer has a thickness of is H2, and H1>H2.

In some embodiments, the quantum dot light-emitting layer includes a first light-emitting portion and a second light-emitting portion, the first light-emitting portion being configured to emit a first-color light, and the second light-emitting portion being configured to emit a second-color light, and the second hole transport layer includes a first transport portion and a second transport portion, the first transport portion being located at a side of the first light-emitting portion close to the first hole transport layer, and the second transport portion being located at a side of the second light-emitting portion close to the first hole transport layer, and the first transport portion having a thickness of H3, and the second transport portion having a thickness of H4, and H3/H4.

In some embodiments, when a wavelength of the first-color light is greater than a wavelength of the second-color light, H3>H4.

In some embodiments, the quantum dot light-emitting layer further includes a third light-emitting portion, the third light-emitting portion being configured to emit a third-color light, and the second hole transport layer further includes a third transport portion, the third transport portion being located at a side of the third light-emitting portion close to the first hole transport layer, and the third transport portion having a thickness of H5, and H3, H4, and H5 being different from each other.

In some embodiments, when the wavelength of the second-color light is greater than a wavelength of the third-color light, H4>H5.

In some embodiments, the quantum dot light-emitting layer includes a first light-emitting portion and a second light-emitting portion, the first light-emitting portion being configured to emit a first-color light, and the second light-emitting portion being configured to emit a second-color light, and the second hole transport layer includes a first transport portion and a second transport portion, and the first hole transport layer includes a fourth transport portion and a fifth transport portion, the first light-emitting portion, the first transport portion, and the fourth transport portion being sequentially stacked along a first direction, and the second light-emitting portion, the second transport portion, and the fifth transport portion being sequentially stacked along the first direction, and the first transport portion having a thickness of H3, the second transport portion having a thickness of H4, the fourth transport portion having a thickness of H6, and the fifth transport portion having a thickness of H7, and (H3+H6)+ (H4+H7).

In some embodiments, when a wavelength of the first-color light is greater than a wavelength of the second-color light, (H3+H6)> (H4+H7).

In some embodiments, the quantum dot light-emitting layer further includes a third light-emitting portion, the third light-emitting portion being configured to emit a third-color light, the second hole transport layer further includes a third transport portion, and the first hole transport layer includes a sixth transport portion, the third light-emitting portion, the third transport portion, and the sixth transport portion being sequentially stacked along the first direction, and the third transport portion having a thickness of H5, and the sixth transport portion having a thickness of H8, and (H3+H6), (H4+H7), and (H5+H8) being different from each other.

In some embodiments, when the wavelength of the second-color light is greater than a wavelength of the third-color light, (H4+H7)> (H5+H8).

In some embodiments, the quantum dot light-emitting layer includes a first light-emitting portion and a second light-emitting portion, the first light-emitting portion being configured to emit a first-color light, and the second light-emitting portion being configured to emit a second-color light, and the second hole transport layer includes a first transport portion and a second transport portion, the first transport portion being located at a side of the first light-emitting portion close to the first hole transport layer, and the second transport portion being located at a side of the second light-emitting portion close to the first hole transport layer, and the first transport portion having a refractive index of n1, and the second transport portion having a refractive index of n2, and n1≠n2.

In some embodiments, when a wavelength of the first-color light is greater than a wavelength of the second-color light, n1>n2.

In some embodiments, the quantum dot light-emitting layer further includes a third light-emitting portion, the third light-emitting portion being configured to emit a third-color light, and the second hole transport layer further includes a third transport portion, the third transport portion being located at a side of the third light-emitting portion close to the first hole transport layer, and the third transport portion having a refractive index of n3, and n1, n2, and n3 being different from each other.

In some embodiments, when the wavelength of the second-color light is greater than a wavelength of the third-color light, n2>n3.

The quantum dot light-emitting diode includes all the technical solutions of the light-emitting element according to any one of the above implementations, and therefore has at least all the beneficial effects brought by the technical solutions of the above embodiments, which will not be described in detail here.

In a fourth aspect of the present application, a quantum dot display panel is provided. The quantum dot display panel includes: a light-emitting element as provided in the first aspect, or a light-emitting element fabricated according to the second aspect, or a quantum dot light-emitting diode fabricated according to the third aspect.

The quantum dot display panel includes a light-emitting element or a quantum dot light-emitting diode of any one of the above implementations. The quantum dot display panel employs all the technical solutions of all the above embodiments, and therefore has at least all the beneficial effects brought by the technical solutions of the above embodiments, which will not be described in detail here.

The quantum dot display panel may be any apparatus with a display function, for example, a mobile device, such as a mobile phone, a tablet computer, a laptop computer, a palmtop computer, a vehicle-mounted electronic device, a wearable device, an ultra-mobile personal computer (UMPC), a netbook, or a personal digital assistant (PDA), or a non-mobile device, such as a personal computer (PC), a television (TV), a teller machine, or a self-service machine.

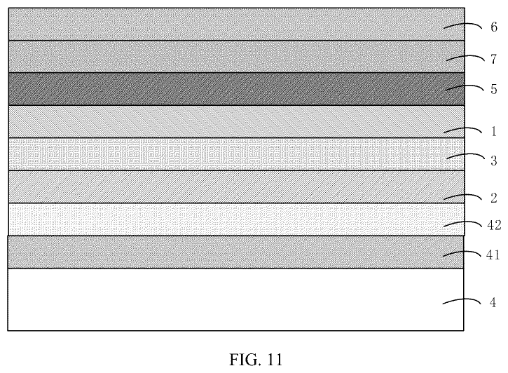

Referring to FIG. 11, in some embodiments, the quantum dot display panel includes a substrate 4, a bottom electrode 41, a first hole transport layer 2, a second hole transport layer 3, a light-emitting layer 1 (or a quantum dot light-emitting layer), an electron transport layer 5, and a top electrode 6 that are sequentially stacked.

The substrate 4 may be a rigid glass or a flexible polyimide (PI) film. The quantum dot display panel according to this embodiment of the present application may be a quantum dot display panel with a top-emitting quantum dot light-emitting diode, where the bottom electrode 41 serves as the anode, and the top electrode 6 serves as the cathode.

When electrons and holes enter the quantum dot light-emitting layer through the electron transport layer 5 and the hole transport layer, respectively, the quantum dots in the quantum dot light-emitting layer are excited by exciton energy and emit light. In addition, because of the quantum confinement effect of quantum dots, the wavelength of the light emitted by the recombination of electrons and holes varies with the size of the quantum dots, and quantum dots of different sizes emit light of different colors. For example, the quantum dot light-emitting layer may include blue quantum dots, green quantum dots, or red quantum dots. The blue quantum dots may be ZnCdS, ZnCdS/ZnS, ZnSe/ZnS, or the like. The green quantum dots may be ZnCdSeS, ZnCdSeS/ZnS, or the like. The red quantum dots may be CdSe/CdS, CdSe/ZnSe, ZnCdSeS/ZnS, or the like.

The bottom electrode 41 may have a reflective surface to reflect light rays emitted by the light-emitting layer 1 (or the quantum dot light-emitting layer), and the top electrode 6 is semi-transflective, such that a microcavity effect for the light rays emitted by the light-emitting layer 1 (or the quantum dot light-emitting layer) can be achieved between the top electrode 6 and the bottom electrode 41. The anode can be made of high work function metals and metal oxides, such as indium tin oxide, indium zinc oxide, or elemental gold. The hole transport layer is made of polytriphenylamine (Poly-TPD), TFB, PVK, N,N′-diphenyl-N,N′-(1-naphthyl)-1, l′-biphenyl-4,4′-diamine (NPB), 4,4′-cyclohexyl bis [N,N-di(4-methylphenyl) aniline] (TAPC), 4,4′,4″-tris (carbazol-9-yl)triphenylamine (TCTA), 2,6-dimethoxyphenol (mCP), 4,4′-di(9-carbazolyl) biphenyl (CBP), 3,3-di(carbazolyl) biphenyl (mCBP), 4,4′-bis(9-carbazolyl)-2,2′-dimethylbiphenyl (CDBP), NiO, Cu2O, or CuSCN. The electron transport layer 5 is made of ZnO, SnO2, ZnMgO, ZnALO, ZnGaO, or TiO2. The cathode may be made of a low work function metal or alloys thereof, such as Al, Ag, or Mg—Ag alloys.

The quantum dot display panel may further include a hole injection layer 42, and the hole injection layer 42 may be disposed between the bottom electrode 41 and the first hole transport layer 2. The hole injection layer 42 can increase the concentration of holes, thereby improving the light-emitting efficiency. The quantum dot display panel may further include an electron injection layer 7, and the electron injection layer 7 may be disposed between the top electrode 6 and the electron transport layer 5. The electron injection layer 7 can increase the concentration of electrons, thereby improving the light-emitting efficiency.

Through the coordination of the hole injection layer 42, the first hole transport layer 2, the second hole transport layer 3, the electron transport layer 5, and the electron injection layer 7, the light-emitting efficiency of the quantum dot display panel can be further improved.

The beneficial effects described above are further illustrated by the embodiments and comparative examples below.

### Experimental Example 1

A substrate was taken, and a first hole transport layer was fabricated using a mixture of TFB and ethylenediamine, where a doping ratio of ethylenediamine is 10%. A mixture of TFB and ethane-1,2-diyl bis(4-azido-2,3,5,6-tetrafluorobenzoate) was disposed on the first hole transport layer, where ethane-1,2-diyl bis(4-azido-2,3,5,6-tetrafluorobenzoate) contained an azido, and a doping ratio of ethane-1,2-diyl bis(4-azido-2,3,5,6-tetrafluorobenzoate) was 10%, and a second hole transport layer and a light-emitting layer were fabricated through a direct photolithography process. An electron transport layer, an electron injection layer, and a top electrode were sequentially fabricated on the light-emitting layer, to obtain a quantum dot display panel. A driving voltage of the quantum dot display panel at a luminance of 500 nit was measured.

### Comparative Example 1

A quantum dot display panel was fabricated with reference to Experimental example 1, except that the light-emitting layer was fabricated through a direct photolithography process on the first hole transport layer, and that no second hole transport layer was disposed.

A driving voltage of the quantum dot display panel at a luminance of 500 nit was measured.

### Comparative Example 2

A quantum dot display panel was fabricated with reference to Experimental example 1, with a difference that the second hole transport layer and the light-emitting layer were fabricated on the substrate through a direct photolithography process, and that no first hole transport layer was disposed.

A driving voltage of the quantum dot display panel at a luminance of 500 nit was measured.

### Comparative Example 3

A quantum dot display panel was fabricated with reference to Experimental example 1, with a difference that the first hole transport layer was fabricated using TFB, the second hole transport layer was fabricated using TFB, and that the light-emitting layer was fabricated on the substrate through a direct photolithography process. A driving voltage of the quantum dot display panel at a luminance of 500 nit was measured.

TABLE 1

| | First hole | Second hole | Driving voltage | |
|---|---|---|---|---|
| | transport layer | transport layer | @500 nit | |
| Experimental | TFB + | TFB + azido | ≥4.5 | V |
| example 1 | ethylenediamine | | | |
| Comparative | TFB + | \ | ≥2.7 | V |
| example 1 | ethylenediamine | | | |
| Comparative | \ | TFB + azido | ≥7 | V |
| example 2 | | | | |
| Comparative | TFB | TFB | ≥3 | V |
| example 3 | | | | |

It can be seen from Comparative examples 1 and 2 that, compared to the addition of a thermal crosslinking group in the hole transport material, the driving voltage of the fabricated quantum dot display panel is increased by the addition of a plurality of vphotosensitive groups in the hole transport material. This indicates that the photosensitive groups reduce the electrical performance of the hole transport layer.

It can be seen from Experimental example 1 and Comparative example 2 that, compared to using the second hole transport layer fabricated by the hole transport material and the photosensitive groups, the driving voltage of the fabricated quantum dot display panel is lowered by adding the first hole transport layer fabricated by the hole transport material and the thermal crosslinking group. This indicates that stacking the first hole transport layer and the second hole transport layer can improve the overall electrical performance of the hole transport layer.

It can be seen from Experimental example 1 and Comparative example 3 that, compared to the hole transport layer fabricated without the thermal crosslinking group and the photosensitive groups, the driving voltage of the fabricated quantum dot display panel is increased using the first hole transport layer fabricated by the hole transport material and the thermal crosslinking group and the second hole transport layer fabricated by the hole transport material and the photosensitive groups, but the second hole transport layer fabricated by the hole transport material and the photosensitive groups can be fabricated together with the light-emitting layer through a direct photolithography process, thereby improving the precision of light-emitting portions in the light-emitting layer.

The foregoing descriptions are merely specific implementations of the present application, but are not intended to limit the protection scope of the present application. Any equivalent modification or replacement readily figured out by a person skilled in the art within the technical scope disclosed in the present application shall fall within the protection scope of the present application. Therefore, the scope of protection of the present application shall be subject to the scope of protection of the claims.

What is claimed is:

1. A light-emitting element, comprising:
a light-emitting layer;
a first hole transport layer disposed at a side of the light-emitting layer; and
a second hole transport layer disposed between the first hole transport layer and the light-emitting layer, the second hole transport layer comprising a second hole transport material host and a plurality of photosensitive groups that crosslink the second hole transport material host, and a hole mobility of the first hole transport layer being greater than that of the second hole transport layer.

2. The light-emitting element according to claim 1, wherein the first hole transport layer comprises a first hole transport material and a plurality of first crosslinking groups that crosslinks the first hole transport material;
and, a doping ratio of the first crosslinking groups in the first hole transport layer ranges from 5% to 20%;
and, the first crosslinking groups are a plurality of thermal crosslinking groups; or, the first crosslinking groups comprise one or more of an aliphatic polyamine crosslinking group, an alicyclic polyamine crosslinking group, an aromatic polyamine crosslinking group, a phenolic crosslinking group, and an anhydride crosslinking group.

3. The light-emitting element according to claim 1, wherein the photosensitive groups comprise one or more of a benzophenone group and an azido-containing group;
and, a doping ratio of the photosensitive groups in the second hole transport layer ranges from 5% to 20%.

4. The light-emitting element according to claim 2, wherein at least one of the first hole transport material and the second hole transport material host is one of TFB, PVK, and Spiro-MeOTAD.

5. The light-emitting element according to claim 1, wherein the first hole transport layer has a thickness of H1, and the second hole transport layer has a thickness of H2, and H1>H2.

6. The light-emitting element according to claim 1, wherein the light-emitting layer comprises a first light-emitting portion and a second light-emitting portion, the first light-emitting portion being configured to emit a first-color light, and the second light-emitting portion being configured to emit a second-color light, and the second hole transport layer comprises a first transport portion and a second transport portion, the first transport portion being located at a side of the first light-emitting portion close to the first hole transport layer, and the second transport portion being located at a side of the second light-emitting portion close to the first hole transport layer, and the first transport portion having a thickness of H3, and the second transport portion having a thickness of H4, and H3≠H4;
and, when a wavelength of the first-color light is greater than that of the second-color light, H3>H4;
and, the light-emitting layer further comprises a third light-emitting portion, the third light-emitting portion being configured to emit a third-color light, and the second hole transport layer further comprises a third transport portion, the third transport portion being located at a side of the third light-emitting portion close to the first hole transport layer, and the third transport portion having a thickness of H5, and H3, H4, and H5 being different from each other;
and, when the wavelength of the second-color light is greater than a wavelength of the third-color light, H4>H5.

7. The light-emitting element according to claim 1, wherein the light-emitting layer comprises a first light-emitting portion and a second light-emitting portion, the first light-emitting portion being configured to emit a first-color light, and the second light-emitting portion being configured to emit a second-color light, and the second hole transport layer comprises a first transport portion and a second transport portion, and the first hole transport layer comprises a fourth transport portion and a fifth transport portion, the first light-emitting portion, the first transport portion, and the fourth transport portion being sequentially stacked along a first direction, and the second light-emitting portion, the second transport portion, and the fifth transport portion being sequentially stacked along the first direction, and the first transport portion having a thickness of H3, the second transport portion having a thickness of H4, the fourth transport portion having a thickness of H6, and the fifth transport portion having a thickness of H7, and (H3+H6)+ (H4+H7);
and, when a wavelength of the first-color light is greater than a wavelength of the second-color light, (H3+H6)> (H4+H7);
and, the light-emitting layer further comprises a third light-emitting portion, the third light-emitting portion being configured to emit a third-color light, the second hole transport layer further comprises a third transport portion, and the first hole transport layer comprises a sixth transport portion, the third light-emitting portion, the third transport portion, and the sixth transport portion being sequentially stacked along the first direction, and the third transport portion having a thickness of H5, and the sixth transport portion having a thickness of H8, (H3+H6), (H4+H7), and (H5+H8) being different from each other;
and, when the wavelength of the second-color light is greater than a wavelength of the third-color light, (H4+H7)> (H5+H8).

8. The light-emitting element according to claim 1, wherein the light-emitting layer comprises a first light-emitting portion and a second light-emitting portion, the first light-emitting portion being configured to emit a first-color light, and the second light-emitting portion being configured to emit a second-color light, and the second hole transport layer comprises a first transport portion and a second transport portion, the first transport portion being located at a side of the first light-emitting portion close to the first hole transport layer, and the second transport portion being located at a side of the second light-emitting portion close to the first hole transport layer, and the first transport portion having a refractive index of n1, and the second transport portion having a refractive index of n2, and n1≠n2;
and, when a wavelength of the first-color light is greater than a wavelength of the second-color light, n1>n2;
and, the light-emitting layer further comprises a third light-emitting portion, the third light-emitting portion being configured to emit a third-color light, and the second hole transport layer further comprises a third transport portion, the third transport portion being located at a side of the third light-emitting portion close to the first hole transport layer, and the third transport portion having a refractive index of n3, and n1, n2, and n3 being different from each other;
and, when the wavelength of the second-color light is greater than a wavelength of the third-color light, n2>n3.

9. A fabrication method for a light-emitting element, comprising:
providing a substrate;
fabricating a first hole transport layer on the substrate;
disposing a first material on the first hole transport layer, the first material comprising a second hole transport material host and a photosensitive reactant, and exposing a first target region to excite the photosensitive reactant within the first target region into a plurality of photosensitive groups that crosslink the second hole transport material host; and
disposing a first light-emitting material on the first material, and developing the first material and the first light-emitting material to form a light-emitting layer and a second hole transport layer in the first target region to fabricate the light-emitting element,
wherein a hole mobility of the first hole transport layer is greater than a hole mobility of the second hole transport layer.

10. The fabrication method for a light-emitting element according to claim 9, wherein the disposing a first light-emitting material on the first material, and developing the first material host and the first light-emitting material comprises:
disposing the first light-emitting material on the first material, and exposing the first target region to cause a photo-crosslinking reaction of the first light-emitting material within the first target region;
developing the first light-emitting material to dissolve the first light-emitting material outside the first target region to obtain the light-emitting layer;
developing the first material to dissolve the first material outside the first target region to obtain the second hole transport layer.

11. The fabrication method for a light-emitting element according to claim 10, wherein the developing the first light-emitting material to obtain a first light-emitting portion for emitting a first-color light, and developing the first material to obtain a first transport portion connected to the first light-emitting portion; and after the developing the first material, the method further comprises:
disposing a second material on the first hole transport layer and the first light-emitting material, the second material comprising a second hole transport material host and a photosensitive reactant, and exposing a second target region to excite the photosensitive reactant within the second target region into a plurality of photosensitive groups that crosslink the second hole transport material host; and
disposing a second light-emitting material on the second material, and developing the second material and the second light-emitting material to form a second transport portion and a second light-emitting portion for emitting a second-color light in the second target region, such that the light-emitting element is fabricated.

12. A quantum dot light-emitting diode, comprising:
a quantum dot light-emitting layer;
a first hole transport layer disposed at a side of the quantum dot light-emitting layer; and
a second hole transport layer disposed between the first hole transport layer and the quantum dot light-emitting layer, the second hole transport layer comprising a second hole transport material host and a plurality of photosensitive group that crosslink the second hole transport material host, and a hole mobility of the first hole transport layer being greater than a hole mobility of the second hole transport layer.

13. The quantum dot light-emitting diode according to claim 12, wherein the photosensitive groups comprise one or more of a benzophenone group and an azido-containing group;
and, a doping ratio of the photosensitive groups in the second hole transport layer ranges from 5% to 20%.

14. The quantum dot light-emitting diode according to claim 12, wherein the first hole transport layer has a thickness of H1, and the second hole transport layer has a thickness of H2, and H1>H2.

15. The quantum dot light-emitting diode according to claim 12, wherein the quantum dot light-emitting layer comprises a first light-emitting portion and a second light-emitting portion, the first light-emitting portion being configured to emit a first-color light, and the second light-emitting portion being configured to emit a second-color light, and the second hole transport layer comprises a first transport portion and a second transport portion, the first transport portion being located at a side of the first light-emitting portion close to the first hole transport layer, and the second transport portion being located at a side of the second light-emitting portion close to the first hole transport layer, and the first transport portion having a thickness of H3, and the second transport portion having a thickness of H4, and H3/H4;
and, when a wavelength of the first-color light is greater than a wavelength of the second-color light, H3>H4;
and, the quantum dot light-emitting layer further comprises a third light-emitting portion, the third light-emitting portion being configured to emit a third-color light, and the second hole transport layer further comprises a third transport portion, the third transport portion being located at a side of the third light-emitting portion close to the first hole transport layer, and the third transport portion having a thickness of H5, and H3, H4, and H5 being different from each other;
and, when the wavelength of the second-color light is greater than a wavelength of the third-color light, H4>H5.

16. The quantum dot light-emitting diode according to claim 12, wherein the quantum dot light-emitting layer comprises a first light-emitting portion and a second light-emitting portion, the first light-emitting portion being configured to emit a first-color light, and the second light-emitting portion being configured to emit a second-color light, and the second hole transport layer comprises a first transport portion and a second transport portion, and the first hole transport layer comprises a fourth transport portion and a fifth transport portion, the first light-emitting portion, the first transport portion, and the fourth transport portion being sequentially stacked along a first direction, and the second light-emitting portion, the second transport portion, and the fifth transport portion being sequentially stacked along the first direction, and the first transport portion having a thickness of H3, the second transport portion having a thickness of H4, the fourth transport portion having a thickness of H6, and the fifth transport portion having a thickness of H7, and (H3+H6)≠(H4+H7);
and, when a wavelength of the first-color light is greater than a wavelength of the second-color light, (H3+H6)> (H4+H7);
and, the quantum dot light-emitting layer further comprises a third light-emitting portion, the third light-emitting portion being configured to emit a third-color light, the second hole transport layer further comprises a third transport portion, and the first hole transport layer comprises a sixth transport portion, the third light-emitting portion, the third transport portion, and the sixth transport portion being sequentially stacked along the first direction, and the third transport portion having a thickness of H5, and the sixth transport portion having a thickness of H8, and (H3+H6), (H4+H7), and (H5+H8) being different from each other;
and, when the wavelength of the second-color light is greater than a wavelength of the third-color light, (H4+H7)> (H5+H8).

17. The quantum dot light-emitting diode according to claim 12, wherein the quantum dot light-emitting layer comprises a first light-emitting portion and a second light-emitting portion, the first light-emitting portion being configured to emit a first-color light, and the second light-emitting portion being configured to emit a second-color light, and the second hole transport layer comprises a first transport portion and a second transport portion, the first transport portion being located at a side of the first light-emitting portion close to the first hole transport layer, and the second transport portion being located at a side of the second light-emitting portion close to the first hole transport layer, and the first transport portion having a refractive index of n1, and the second transport portion having a refractive index of n2, and n1≠n2;
and, when a wavelength of the first-color light is greater than a wavelength of the second-color light, n1>n2;
and, the quantum dot light-emitting layer further comprises a third light-emitting portion, the third light-emitting portion being configured to emit a third-color light, and the second hole transport layer further comprises a third transport portion, the third transport portion being located at a side of the third light-emitting portion close to the first hole transport layer, and the third transport portion having a refractive index of n3, and n1, n2, and n3 being different from each other;
and, when the wavelength of the second-color light is greater than a wavelength of the third-color light, n2>n3.

18. A quantum dot display panel, comprising: a light-emitting element according to claim 1.

19. A quantum dot display panel, comprising: a light-emitting element fabricated by the fabrication method for a light-emitting element according to claim 9.

20. A quantum dot display panel, comprising: a quantum dot light-emitting diode according to claim 12.
